(19) United States
(12) Patent Application Publication
(10) Pub. No.: US 2025/0137583 A1
(43) Pub. Date: May 1, 2025

(54) DISPLAY DEVICE HOLDER AND DISPLAY DEVICE HAVING THE SAME

(71) Applicant: Jolly Innovation Technology Co., Ltd., Guangzhou (CN)

(72) Inventor: Li Xiao, Shenzhen (CN)

(21) Appl. No.: 18/926,817

(22) Filed: Oct. 25, 2024

(30) Foreign Application Priority Data
Oct. 27, 2023 (CN) 202322911041.3

(51) Int. Cl. F16M 13/02; H05K 5/02

(52) U.S. Cl. CPC F16M 13/022; H05K 5/0204; F16M 2200/024; F16M 2200/06

(57) ABSTRACT

The present disclosure provides a display device holder and display device having the same. The display device holder comprises a fixing member, a mounting member configured to mount a display module, a supporting member rotatably connected to the fixing member and the mounting member, a locking device movably arranged on the fixing member, and a locking member attached to the supporting member, wherein the supporting member is changeable between a locked state and an unlocked state, the locking member engages with the locking device so as to hold the supporting member at a predefined position. A display device comprises a display module and the display device holder.

### CROSS-REFERENCE TO RELATED APPLICATIONS

This application claims the benefit of priority to Chinese Patent Application Number 202322911041.3 filed on Oct. 27, 2023, in the China National Intellectual Property Administration. The entire contents of the above-identified application are hereby incorporated by reference.

### Technical Field

The present invention relates to the field of display devices, in particular to a holder for a display device.

### BACKGROUND

As the applications of televisions and computer display devices become more widespread, the display devices are installed in more and more ways. Through a ceiling-mounted display device holder, a display device can be suspended from a top mounting surface such as a ceiling. A foldable holder is designed to facilitate easy storage and save space. Foldable ceiling-mounted display device holders available on the market may loosen on their own. For applications in recreational vehicles and earthquake-prone environments, the presence of safety hazards is very dangerous.

### BRIEF DESCRIPTION OF DRAWINGS

Embodiments of the present disclosure will now be described, by way of embodiment, with reference to the attached figures. The structure, operation, and advantages of the present invention will become further apparent upon consideration of the following description taken in conjunction with the accompanying figures. The figures are intended to be illustrative, and not limiting.

FIG. 1 is a perspective view of a display device including a display device holder according to a first embodiment of the present disclosure, wherein the display device holder is changeable between in an unfolded state (a) and in a folded state (b).

FIG. 2 shows a perspective view of the display device holder according to the first embodiment of FIG. 1.

FIG. 3 shows another perspective view of the display device holder according to the first embodiment of FIG. 1.

FIG. 4 is an exploded view of the display device holder according to the first embodiment of FIG. 1.

FIG. 5 is a cross-sectional view of a locking device of the display device according to the first embodiment of FIG. 1, wherein the locking device is in a first position.

FIG. 6 is a cross-sectional view of a locking device of the display device according to the first embodiment of FIG. 1, wherein the locking device is in a second position.

FIG. 7 is an exploded view of a hinge mechanism according to the first embodiment of FIG. 1.

FIG. 8 shows a perspective view of a connecting member according to the first embodiment of FIG. 1.

FIG. 9 shows a perspective view of the display device holder according to the first embodiment of FIG. 1, wherein the display holder is in a folded state.

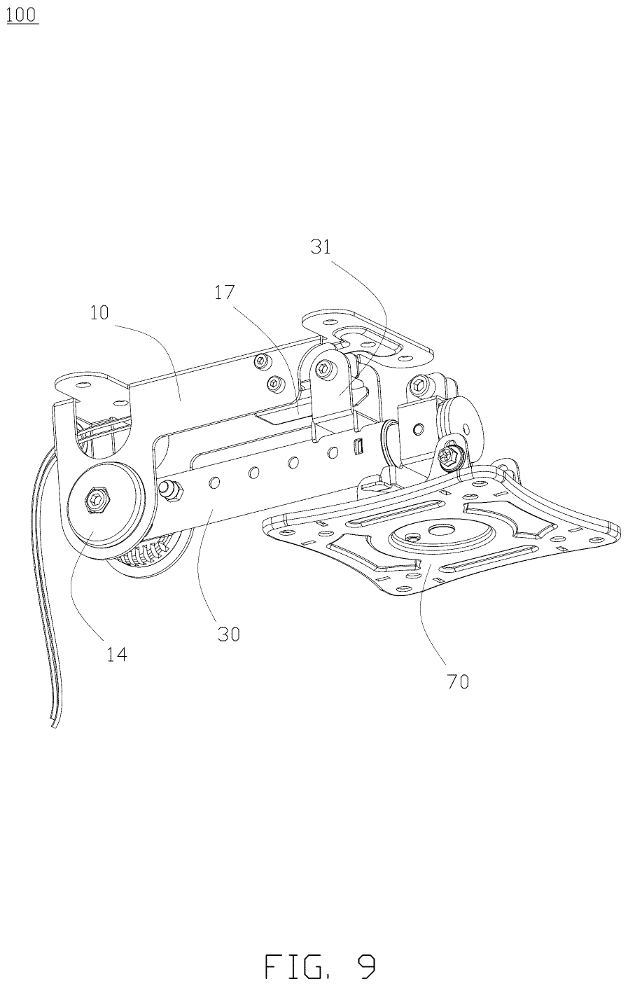

FIG. 10 shows a perspective view of a display device holder according to a second embodiment.

### DETAILED DESCRIPTION

In the description that follows, numerous details are outlined to provide a thorough understanding of the present invention. It will be appreciated by those skilled in the art that variations of these specific details are possible while still achieving the results of the present invention.

Exemplary illustrative embodiments of the invention should be interpreted as example(s) and non-limiting. The relationship between various arms, where they are located, their composition(s), their operation and sometimes their sizes relative to the desired operation of the invention are not significant.

### First Embodiment

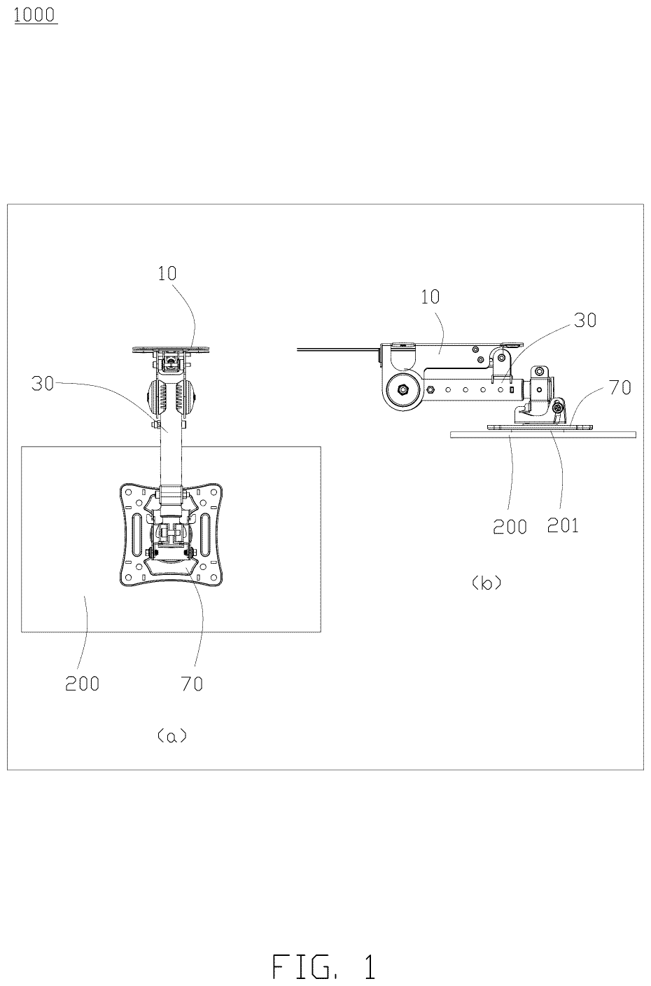

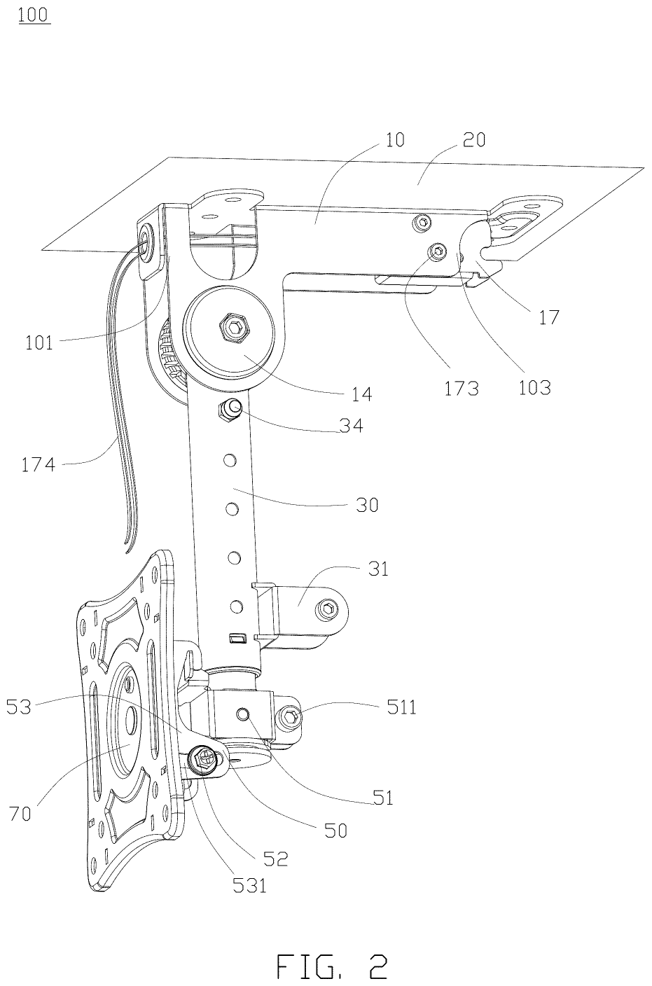

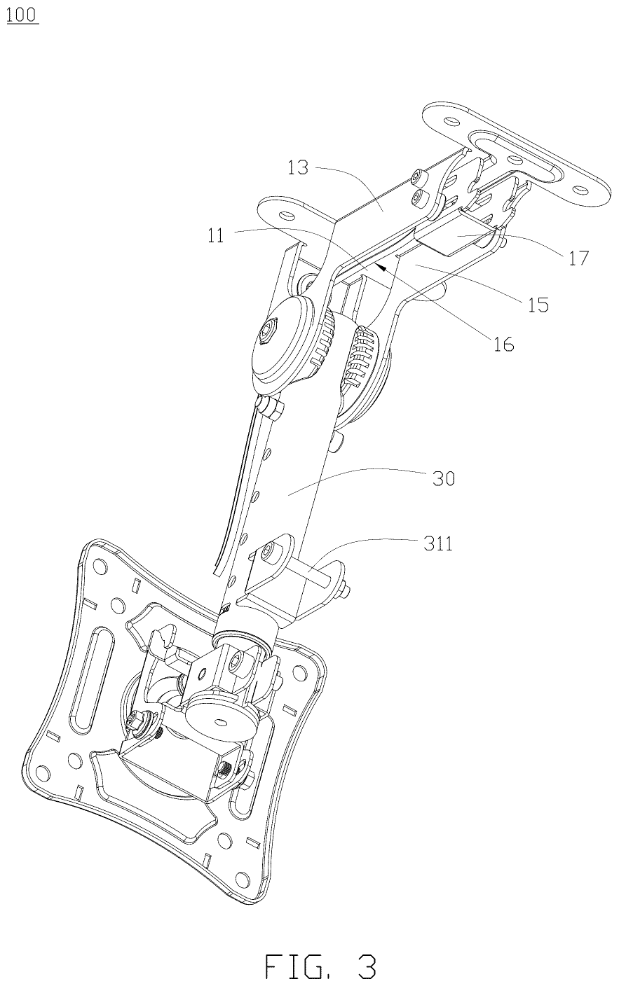

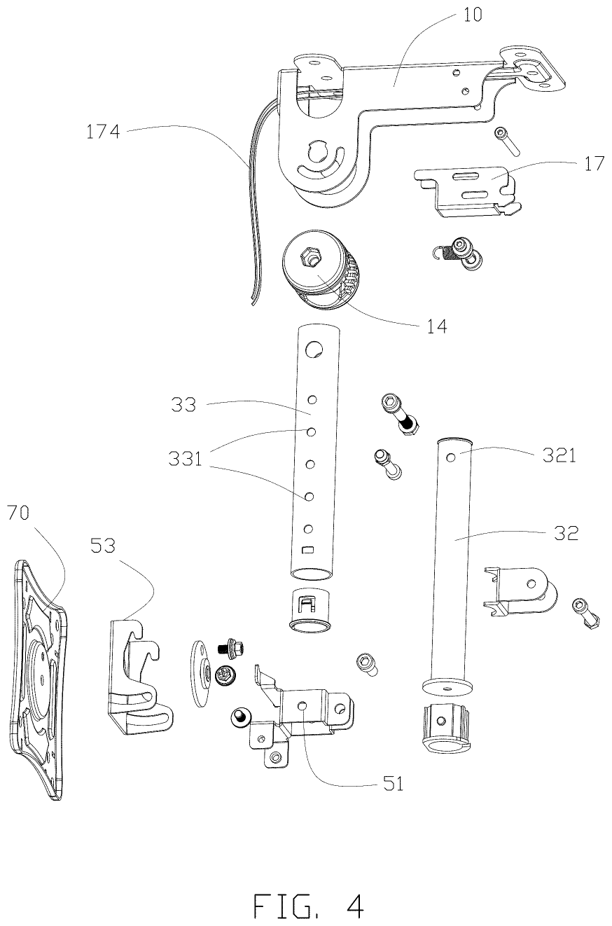

Referring to FIG. 1 to FIG. 6, a display device 1000 includes a display device holder 100 and a display module 200 including a display screen. The display device holder 100 is provided with a fixing member 10, a supporting member 30 rotatably connected to the fixing member 10 at one end of the supporting member 30, a connecting member 50 connected to another end of the supporting member 30 which is away from the fixing member 10, and a mounting member 70 arranged on the connecting member 50. A joint portion 201 is arranged on a side, close to the mounting member 70, of the display module 200, and the display module 200 is connected to the display device holder 100 via the joint portion 201. The supporting member 30 can rotate relative to the fixing member 10, therefore, the display device holder 100 is switchable between a folded state and an unfolded state.

The fixing member 10 is located at the top of a whole of the display device holder 100 for mounting the display device holder 100 on a mounting surface 20 of an object. The fixing member 10 includes a first end 101 connected to the supporting member 30 and a second end 103 opposite to the first end 101. The fixing member 10 further includes a first position-limiting wall 13, a fixing plate 11 and a second position-limiting wall 15 which are connected in sequence. The fixing plate 11 is configured to directly contact with the mounting surface 20, and is roughly of an I-shaped flat plate. The fixing plate 11 is formed with a plurality of mounting holes, and the fixing plate 11 is fixed to the mounting surface 20 by screw mounting. The mounting surface 20 may be a wall, a ceiling, a roof of a recreational vehicle, a cupboard and the like. It can be understood that the fixing plate 11 may also be of other shapes that are conducive to improving stability of mounting, and may be set in different shapes according to actual needs. The first position-limiting wall 13 and the second position-limiting wall 15 are arranged opposite to each other on two sides of the fixing plate 11 in a width direction, and are respectively bent and extended towards the supporting member 30. The second position-limiting wall 15 is parallel to the first position-limiting wall 13. The first position-limiting wall 13, the fixing plate 11, and the second position-limiting wall 15 cooperatively form a sliding groove 16 for storing a locking device 17.

The locking device 17 is slidably arranged at a position close to the second end 103 of the sliding groove 16. The locking device 17 is configured to lock the supporting member 30 when the supporting member 30 is in a folded state. The locking device 17 includes a main body 171, a position-limiting rod 173, an elastic member 175 and a triggering member 174. The main body 171 is movably mounted to the first position-limiting wall 13 and the second position-limiting wall 15 of the fixing member 10, such that the main body 171 can move back and forth along a length direction of the fixing member 10, to release and hold the supporting member 30. A holding portion 176 is formed on a side, close to the second end 103, of the main body 171. The main body 171 includes two opposite side walls, and a pair of position-limiting holes 172 which are parallel to each other are disposed in each of the two side walls. The position-limiting holes 172 are set to be in an oval shape, and the width is the same as the diameter of the position-limiting rod 173 for the position-limiting rod 173 to pass through. The position-limiting rod 173 is arranged to penetrate through the first position-limiting wall 13, the position-limiting holes 172 and the second position-limiting wall 15, and two ends of the position-limiting rod 173 are fixed to the first position-limiting wall 13 and the second position-limiting wall 15. The main body 171 is movably mounted to the fixing member 10 by the position-limiting rod 173, and the main body 171 moves relative to the position-limiting rod 173 by the position-limiting holes 172.

In the present embodiment, two position-limiting rods 173 are arranged, and the corresponding position-limiting holes 172 are in two pairs, but one or more than two position-limiting holes 172 can be arranged according to actual needs.

It can be appreciated that two position-limiting protrusions 177 are arranged on each of the position-limiting rods 173. One position-limiting protrusion 177 is held between the first position-limiting wall 13 and the main body 171, and the other position-limiting protrusion 177 is held between the second position-limiting wall 15 and the main body 171, such that the two position-limiting protrusions 177 prevent the main body 171 from shaking leftwards and rightwards between the first position-limiting wall 13 and the second position-limiting wall 15.

The elastic member 175 is mounted between the position-limiting rod 173 and the main body 171. One end of the elastic member 175 is connected to the position-limiting rod 173, and the other end of the elastic member 175 is connected to a side, away from the position-limiting rod 173, of the main body 171. When the user pulls the triggering member 174, the main body 171 moves relative to the position-limiting rod 173, the elastic member 175 is then compressed. When the user releases the triggering member 174, the main body 171 moves back, the main body 171 is then reset under a reset force of the elastic member 175.

The elastic member 175 may be a spring, an elastic cord, etc., and the position-limiting rod 173 may be a bolt, a screw, etc.

The holding portion 176 is arranged on a side, away from the supporting member 30, of the locking device 17, and is a concave portion which is concave inwards. The holding portion 176 is formed with a receiving groove 1761 on the side away from the triggering member 174, and the receiving groove 1761 is configured to engaging with the supporting member 30. The bottom surface of the holding portion 176 is provided with a guiding inclined surface 1763, and the guiding inclined surface 1763 is located on a side, away from the fixing member 10, of the receiving groove 1761.

The triggering member 174 wraps around the main body 171 and extends out of the fixing member 10, thereby facilitating easy operation of the triggering member 174 by the user.

The supporting member 30 is of a long-strip structure, i.e., the supporting member 30 is long cylindrical-shaped or cuboid-shaped. The supporting member 30 includes a first rod portion 32, a second rod portion 33 wrapping around the first rod portion 32, and a retaining screw 34. The first rod portion 32 may be a hollow-shaped structure, and a first fixing hole 321 which penetrates through the first rod portion 32 is arranged close to the fixing member 10. The second rod portion 33 is also of a hollow-shaped structure, and a plurality of second fixing holes 331 are arranged at intervals along a length direction of the rod. The second fixing holes 331 penetrate through the second rod portion 33. The first rod portion 32 can slide relative to the second rod portion 33. A relative positional relationship between the first rod portion 32 and the second rod portion 33 may be adjusted when the first rod portion 32 slides relative to the second rod portion 33. Therefore, the first fixing hole 321 may be matched with any one of the second fixing holes 331 by the sliding of the first rod portion 32 and may be fixed by the retaining screw 34. When the first fixing hole 321 matches the second fixing hole 331 closest to the fixing member 10, the supporting member 30 is at its minimum length. When the first fixing hole 321 matches the second fixing hole 331 closest to the connecting member 50, the supporting member 30 is at its maximum length, i.e., the supporting member 30 is of a retractable structure.

A connecting portion 31 is arranged at a position, away from the fixing member 10, of the supporting member 30, and the connecting portion 31 is provided with a locking member 311, and the locking member 311 is connected to the supporting member 30. When the display device holder 100 is in the folded state, the supporting member 30 is substantially parallel to the fixing member 10, and when the connecting portion 31 is attached to the fixing member 10, the locking member 311 is held in the holding portion 176. Therefore, the supporting member 30 can be stably hovered in a horizontal position without falling off.

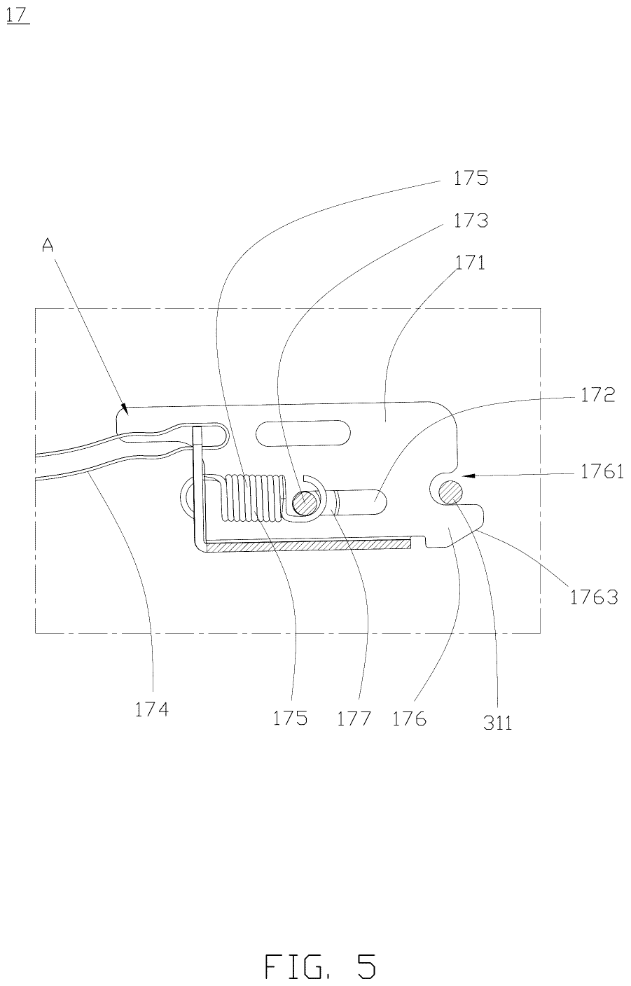

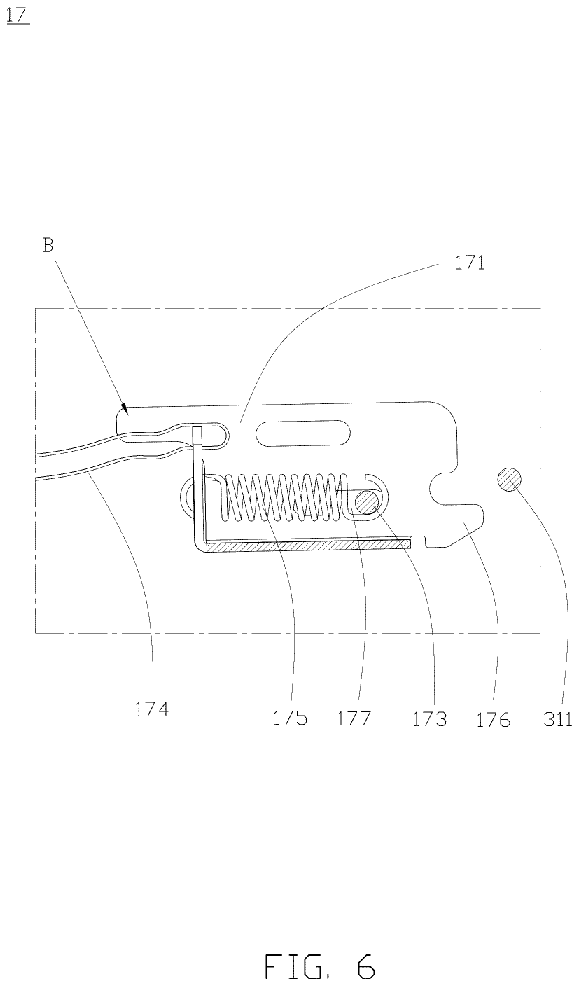

Referring to FIG. 5 and FIG. 6, the operating principle of the locking device 17 is explained below.

When the display device holder 100 is in the folded state, the locking device 17 is in a first position A. The first position A is configured such that the locking member 311 can be clamped into the holding portion 1761, as shown in FIG. 5. The user pulls the triggering member 174, such that the main body 171 moves horizontally in the sliding groove 16 to reach a second position B. The second position B is configured to be a position from which the locking member 311 can rotate to the first position A or a position from which the locking member 311 can be disengaged from the first position A, as shown in FIG. 6. The locking member 311 is gradually disengaged from the receiving groove 1761, the elastic member 175 is compressed, the locking member 311 is disengaged from the holding portion 176, and the supporting member 30 is thus released. When the triggering member 174 is released, the locking device 17 is pushed back to the first position A by the elastic restoring force of the elastic member 175, and the display device holder 100 is capable of being changed from the folded state to the unfolded state by means of an external force.

When the display device holder 100 is in the unfolded state, the locking device 17 is in the second position. The user forcefully pushes the supporting member 30 towards the fixing member 10, and the supporting member 30 rotates relative to the fixing member 10 and moves close to the fixing member 10. Meanwhile, the locking member 311 contacts with the guiding inclined surface 1763 and moves along the guiding inclined surface 1763 towards the receiving groove 1761, meanwhile, the main body 171 is pushed by the supporting member 30 to compress the elastic member 175. When the connecting portion 31 is close to the receiving groove 1761, the main body 171 moves relative to the fixing member 10 under the elastic restoring force of the elastic member 175, such that the locking member 311 is clamped into the receiving groove 1761.

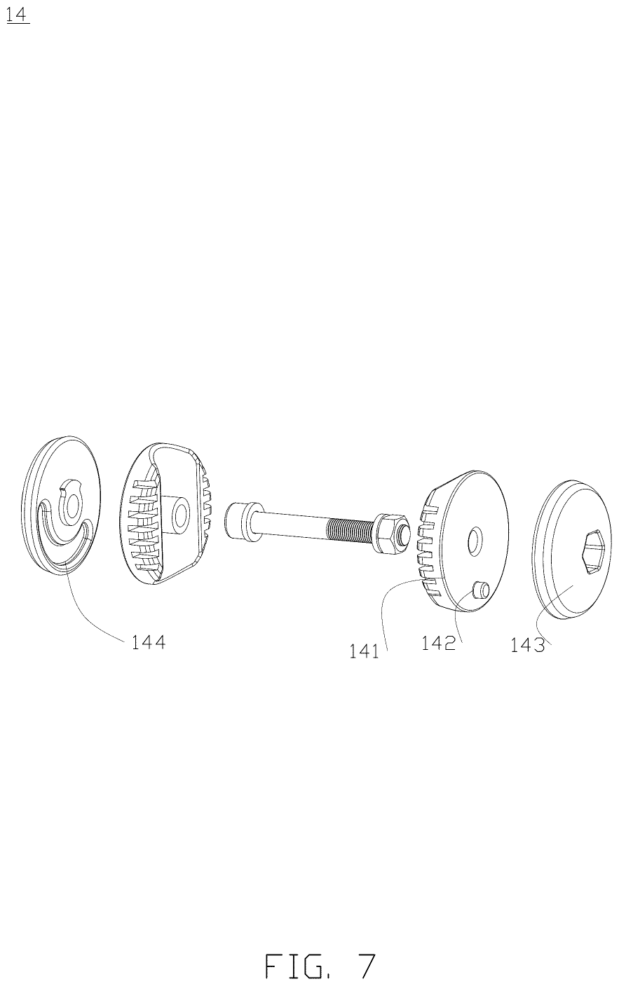

Referring to FIG. 7, the fixing member 10 and the supporting member 30 are connected by a hinge mechanism 14. The hinge mechanism 14 is arranged at a position, away from the fixing surface 11, of the fixing member 10. The hinge mechanism 14 includes a rotation member 141 arranged on the inner side of the first position-limiting wall 13 and the second position-limiting wall 15, and a stop member 143 arranged on the outer side of the first position-limiting wall 13 and the second position-limiting wall 15. The rotation member 141 is provided with a protrusion 142, and the stop member 143 is provided with a stop sliding groove 144 corresponding to the protrusion 142. In the present embodiment, the stop sliding groove 144 is an arc-shaped groove arranged close to the periphery of the stop member 143. The arc-shaped groove may be arranged on a side, away from the fixing member 10, of the stop member 143, and the arc-shaped center faces towards a three-eighths circle of the fixing member 10. The protrusion 142 may slide within the stop sliding groove 144 to drive the supporting member 30 to rotate by 0 to 135° relative to the fixing member 10.

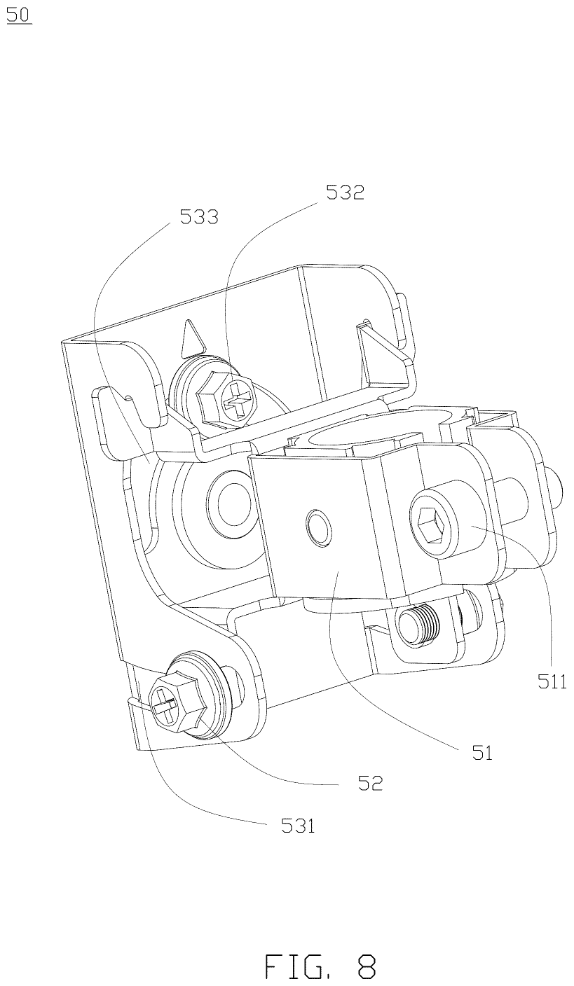

Referring to FIG. 8, the connecting member 50 includes a first bolt 52, an adjusting member 53 connected to the mounting member 70, and a fastener 51 connected to the supporting member 30. A locking bolt 511 is arranged at the position, close to the supporting member 30, of the fastener 51. The adjusting member 53 is provided with a first hole 531 which penetrates through the adjusting member 53, and the first hole 531 is long-strip shaped with a radian. A first bolt 52 is arranged to penetrate through the fastener 51 and the first hole 531. The first bolt 52 can slide within the first hole 531, such that the adjusting member 53 can move by a small amplitude relative to the fastener 51. The adjusting member 53 is provided with a second bolt 532 and a second hole 533, and the second hole 533 is a semi-circular ring with an opening forward the central of the adjusting member. The second bolt 532 penetrates through the second hole 533 and the mounting member 70 for mounting and fixing the mounting member 70 to the adjusting member 53. The mounting member 70 is enabled to rotate relative to the connecting member 50 by adjusting the second bolt 532.

The adjustment methods of the connecting member 50 of the present embodiment are described below. In the first adjustment method, the locking bolt 511 is loosened. An adjusting space is created between the fastener 51 and the supporting member 30, such that the fastener 51 can be adjusted by 360° relative to the supporting member 30. After the fastener 51 is adjusted to a corresponding angle, the locking bolt 511 is locked, and the display device can rotate horizontally by 360°. In the second adjustment method, the first bolt 52 is loosened. A small degree of adjustment of the pitching angle can be achieved by changing the position of the first bolt 52 in the arc-shaped first hole 531. The first bolt 52 is locked after adjustment to a corresponding angle, that is, the pitching angle of the display device in a vertical direction can be adjusted. In the third adjustment method, the second bolt 532 is loosened. The second bolt 532 changes its position in the second hole 533 to drive the mounting member 70 to rotate. After the mounting member 70 rotates to a corresponding angle, the second bolt 532 is locked, that is, the display device can be switched between the horizontal, vertical and oblique screens.

The above three adjustment methods can be completed independently, or a combination of two or three adjustment methods can be completed, such that the display device holder can be located in a variety of different angles, and the viewing experience is enriched.

In summary, as to the display device holder 100 of the present embodiment, the locking member 311 is held by the holding portion 176 under the folded state, and the supporting member 30 will not loosen and fall off, and can cope with motion scenarios such as recreational vehicles and earthquakes. The supporting member 30 can be released by pulling the triggering member 174, and can be changed from the folded state to the unfolded state, with such advantages of safety and stability, and easy operation. In addition, by means of adjusting parts such as the hinge mechanism 14, the locking bolt 511, the first bolt 52, the second bolt 532 and the like, the display device can be used at different angles and can adapt to a variety of scenarios, thereby improving the comfort of the user in the using process.

### Second Embodiment

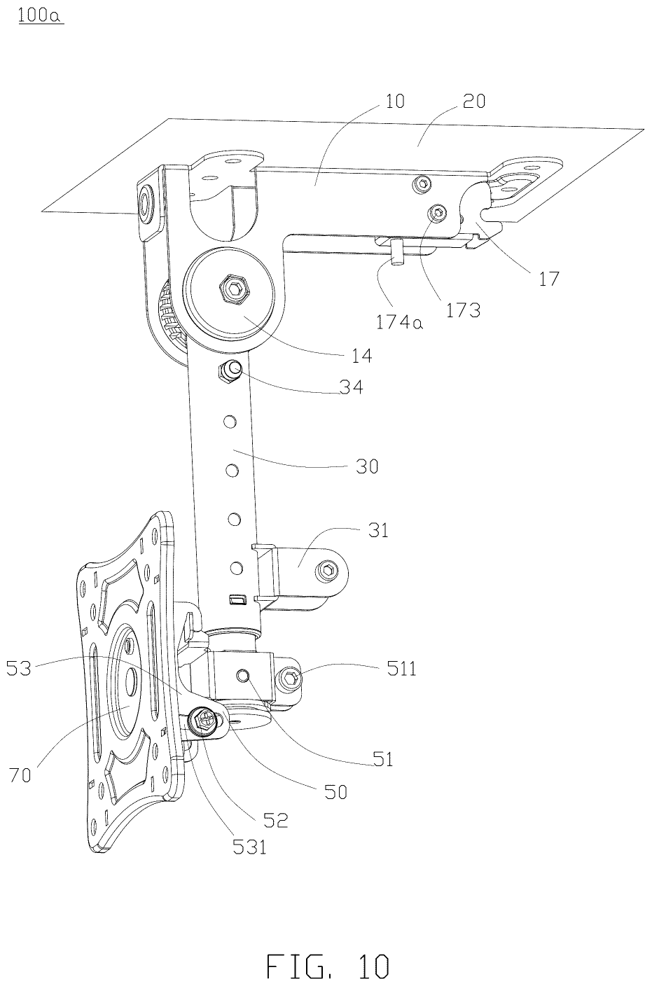

Referring to FIG. 10, the overall structure of the ceiling-mounted display device holder 100a involved in the second embodiment of the present invention is substantially the same as the display device holder 100 of the first embodiment. The difference between the two lies in that the triggering member 174 in the second embodiment is set to be a handle 174a fixed to the locking device 17, and the locking device 17 can move within the fixing member 10 by pulling the handle 174a.

The handle 174a is substantially a long cylinder or a U-shaped member. The handle 174a is arranged on a side, away from the fixing plate 11, of the locking device 17, and during the folded state and the unfolded state, the handle 174a is exposed to the outside to facilitate gripping by a user.

Based on the present embodiment, the same effect as the display device holder 100 of the first embodiment can be achieved.

The contents not described in detail in this specification are known to those skilled in the art.

In the description of the present disclosure, it should be understood that terms such as “center”, “longitudinal”, “lateral”, “length”, “width”, “thickness”, “top”, “bottom”, “front”, “rear”, “left”, “right”, “vertical”, “horizontal”, “upper”, “lower”, “inner”, “outer”, “clockwise”, “counterclockwise”, etc., indicate the orientation or positional relationship based on the orientation or positional relationship shown in the drawings. These terms are used for descriptive purposes and are not to be construed as limiting, indicating, or implying any particular orientation, construction or operation for the devices or arms referred to. Therefore, it should be understood that the terms “first,” “second,” etc., are used for descriptive purposes only and do not imply or suggest any relative importance or indicate the quantity of technical features indicated.

The foregoing illustrates and describes the basic principles and main features of the present disclosure and its advantages. Those skilled in the art should understand that the present disclosure is not limited to the embodiments described above. The embodiments and descriptions in the specification are intended only to illustrate the principles of the present disclosure. Within the scope and spirit of the present disclosure, various modifications and improvements can be made which fall within the scope of protection defined by the appended claims and their equivalents.

What is claimed is:

1. A display device holder, comprising:
a fixing member configured to be fastened to a mounting surface;
a mounting member configured to mount a display module of a display screen;
a supporting member rotatably connected to the fixing member at one end of the supporting member and rotatably connected to the mounting member at another end of the supporting member;
a locking device movably arranged on the fixing member; and
a locking member attached to the supporting member, wherein
the supporting member is changeable between a locked state and an unlocked state, the locking member is engaged with the locking device so as to hold the supporting member at a predefined position; and
wherein the locking member is configured to engage with the locking device or disengage with the locking device, when the locking member engages with the locking device, the supporting member is located in the locked state, when the locking member disengages with the locking device, the supporting member is located in the unlocked state, when the supporting member is located in the unlocked state, the supporting member is rotatable to be apart from the fixing member.

2. The display device holder according to claim 1, wherein
the locking device comprises a main body and a triggering member connected to the main body, the main body is attached to the fixing member and engages with the locking member, the triggering member is configured to extend out of the fixing member and operatable by a user.

3. The display device holder according to claim 2, wherein
the locking device further comprises a rod and an elastic member, two ends of the rod are fixedly connected to the fixing member,
one end of the elastic member is connected to the rod, and another end of the elastic member is connected to the main body,
when the triggering member is operated, the main body moves with respect to the rod to release the locking member, and the elastic member is compressed, and
when the triggering member is released, the elastic member elastically extends thereby moving the main body to an original position.

4. The display device holder according to claim 2, wherein
the main body comprises a holding portion disposed at a location away from the triggering member, the holding portion engages with the locking member, the holding portion is concaved towards the supporting member.

5. The display device holder according to claim 4, wherein
the holding portion defines a receiving groove, a guiding surface is obliquely formed at a bottom surface of the receiving groove, and,
when the supporting member rotates relative to the fixing member, the locking member contacts the guiding surface and slides along the guiding surface into the receiving groove.

6. The display device holder according to claim 2, wherein
the main body includes two opposite side walls, each of the two opposite side walls defines a hole, and
the rod penetrates through the holes of the main body,
a width of the hole is substantially same as a diameter of the rod, the main body is limited in the hole to move relative to the rod by the holes along a length direction of the hole.

7. The display device holder according to claim 6, wherein
the fixing member comprises a fixing plate, a first wall, and a second wall, and
the first wall and the second wall are arranged opposite to each other on two sides of the fixing plate in a width direction and are formed by bending and extending towards the supporting member respectively, and the fixing plate, the first wall and the second wall cooperatively form a sliding groove.

8. The display device holder according to claim 6, wherein
the locking device is arranged within the sliding groove, and two first protrusions are sleeved on the rod, one of the two first protrusions is arranged between the main body and the first wall, another one of the two first protrusions is arranged between the main body and the second wall such that the first protrusions limit the main body.

9. The display device holder according to claim 8, wherein
the display device holder further comprises a hinge mechanism, the hinge mechanism is arranged on an end, of the supporting member, which is away from the fixing member,
the supporting member is rotatably connected to the fixing member by the hinge mechanism.

10. The display device holder according to claim 9, wherein
the hinge mechanism comprises a rotation member and a stop member, and
the rotation member is provided with a second protrusion, the stop member is provided with a stop sliding groove corresponding to the second protrusion, the stop sliding groove is an arc-shaped groove and the second protrusion is slidable within the stop sliding groove to limit a rotation angle of the supporting member.

11. The display device holder according to claim 10, wherein
the arc-shaped groove is a three-eighths circular ring, and the opening of the arc-shaped groove faces towards a central of the fixing member, the second protrusion is configured for sliding within the stop sliding groove to drive the supporting member to rotate by 0 degree to 135 degrees relative to the fixing member.

12. The display device holder according to claim 11, wherein
the supporting member comprises a first rod portion and a second rod portion, the second rod portion is sleeved to the first rod portion, and the first rod portion is slidable relative to the second rod portion.

13. A display device holder comprising:
a fixing member disposed at a topside of the display device holder, the fixing member being configured to be fastened to a mounting surface, the mounting surface being located above the fixing member;
the fixing member including a first end, a second end opposite to the first end, and a sliding groove extending from the first end towards the second end;
a supporting member configured to connect to the first end and rotatable towards a direction away from the first end, the supporting member comprising a locking member; and,
a locking device arranged within the sliding groove, the locking device comprising an opening substantially parallel to the mounting surface,
wherein the supporting member is changeable between a locked state and an unlocked state, the locking member is received in the opening of the locking device and engages with the locking device, so as to hold the supporting member in a locked state, when the locking member is located apart from the opening of the locking device, the supporting member is switchable to an unlocked state.

14. The display device holder according to claim 13, wherein
the locking device comprises a triggering member, extending outside the fixing member at the first end.

15. The display device holder according to claim 13, wherein
the fixing member comprises a fixing plate configured to be paralleled to the mounting surface, the fixing plate is I-shaped flat plate.

16. The display device holder according to claim 13, further comprising
a mounting member configured to mount a display module, and a connecting member connected to one end, of the supporting member, which is away from the locking device;
wherein the connecting member comprises a screw, an adjusting member connected to the mounting member for adjusting an angle defined by the display module and the mounting surface, and a fastener connected to the supporting member, wherein a side of the adjusting member away from the mounting member is connected to the fastener, and
a locking bolt is arranged at the fastener, and the connecting member rotates relative to the supporting member by adjusting the locking bolt.

17. The display device holder according to claim 16, wherein
the adjusting member comprising a first hole which is arc-shaped,
the first bolt is fixedly connected to the fastener, and
the first bolt is slidable within the first hole.

18. The display device holder according to claim 16, wherein
the adjusting member defines a second hole at a side of the mounting member, and comprises a second bolt inserted into the second hole,
the second bolt is connected to the adjusting member and the mounting member, and
the second hole is a semi-circular ring, and the second bolt is slidable in the second hole.

19. A display device comprising:
a display module, and
the display device holder according to claim 1.

20. The display device according to claim 19, wherein
the display module comprises a joint portion which is connected with the mounting member.
